(19) United States
(12) Patent Application Publication
(10) Pub. No.: US 2024/0355834 A1
(43) Pub. Date: Oct. 24, 2024

(54) DISPLAY SUBSTRATE, DISPLAY PANEL, AND DISPLAY APPARATUS

(71) Applicants: Ordos Yuansheng Optoelectronics Co., Ltd., Inner Mongolia (CN); BOE Technology Group Co., Ltd., Beijing (CN)

(72) Inventors: Bo HUANG, Beijing (CN); Jianyun XIE, Beijing (CN); Jingyi XU, Beijing (CN); Hong LIU, Beijing (CN); Yongqiang ZHANG, Beijing (CN); Shuai HAN, Beijing (CN); Zhenhong XIAO, Beijing (CN); Pengyu ZHAO, Beijing (CN); Hao WANG, Beijing (CN); Wanzhi CHEN, Beijing (CN)

(21) Appl. No.: 18/688,049

(22) PCT Filed: Jul. 28, 2022
(86) PCT No.: PCT/CN2022/108713

§ 371 Date: Feb. 29, 2024

(51) Int. Cl. H01L 27/12

(52) U.S. Cl. CPC H01L 27/124; H01L 27/1222

(57) ABSTRACT

A display substrate, a display panel, and a display apparatus. The display substrate includes a base substrate; a gate line extending in a first direction on the base substrate; and a transistor located on the base substrate, where the transistor includes a gate electrode and a first electrode that is located at a side of a layer where the gate electrode is located away from the base substrate, part of the gate line is used as the gate electrode, an orthogonal projection of the gate electrode on the base substrate in a second direction is located within an orthogonal projection of the first electrode on the base substrate in the second direction, and the second direction intersects with the first direction.

### CROSS-REFERENCE TO RELATED APPLICATION

This application is a national phase entry under 35 U.S.C § 371 of International Application No. PCT/CN2022/108713, filed on Jul. 28, 2022, the entire content of which is incorporated herein by reference.

### TECHNICAL FIELD

The present disclosure relates to the field of display technologies, in particular to a display substrate, a display panel, and a display apparatus.

### BACKGROUND

A liquid crystal display (LCD) is light in weight, low in power consumption, high in image quality, weak in radiation and portable. It has gradually replaced a traditional cathode ray tube display (CRT) and been widely used in modern information apparatuses, such as a projector, a three-dimensional (3D) printer, a virtual reality apparatus, and other products.

### SUMMARY

Embodiments of the present disclosure provide a display substrate, a display panel and a display apparatus, and include a specific solution as follows.

In an aspect, the embodiments of the present disclosure provide a display substrate, including:
a base substrate;
a gate line extending in a first direction on the base substrate; and
a transistor located on the base substrate; where the transistor includes a gate electrode and a first electrode that is located at a side of a layer where the gate electrode is located away from the base substrate, part of the gate line is used as the gate electrode, an orthogonal projection of the gate electrode on the base substrate in a second direction is located within an orthogonal projection of the first electrode on the base substrate in the second direction, and the second direction intersects with the first direction.

In some embodiments, in the display substrate according to the embodiments of the present disclosure, the transistor further includes an active layer. The active layer is disposed between the layer where the gate electrode is located and a layer where the first electrode is located.

In some embodiments, in the display substrate according to the embodiments of the present disclosure, an orthogonal projection of the gate line on the base substrate runs through orthogonal projections of first electrodes on the base substrate.

In some embodiments, the display substrate according to the embodiments of the present disclosure further includes a pixel electrode located at a side of a layer where the transistor is located away from the base substrate, and a planarization layer disposed between the layer where the transistor is located and a layer where the pixel electrode is located;
the pixel electrode is electrically connected with the first electrode through a first via hole penetrating through the planarization layer, an orthogonal projection of the first via hole on the base substrate and the orthogonal projection of the gate line on the base substrate have a first overlapping region, and an area ratio of the first overlapping region to the orthogonal projection of the first via hole on the base substrate is greater than ½ and smaller than 1.

In some embodiments, in the display substrate according to the embodiments of the present disclosure, a single side of the orthogonal projection of the first electrode on the base substrate extends beyond that of the orthogonal projection of the first via hole on the base substrate by a distance within 1 μm.

In some embodiments, in the display substrate according to the embodiments of the present disclosure, the active layer includes a first contact region electrically connected with the first electrode, and an orthogonal projection of the first contact region on the base substrate partially overlaps with the orthogonal projection of the gate line on the base substrate.

In some embodiments, in the display substrate according to the embodiments of the present disclosure, the base substrate includes a spacer region, the transistor further includes a second electrode located in the same layer and made of the same material as the first electrode, and an orthogonal projection of the second electrode on the base substrate partially overlaps with the spacer region.

In some embodiments, the display substrate according to the embodiments of the present disclosure further includes an interlayer dielectric layer disposed between the active layer and a layer where the second electrode is located, the second electrode is electrically connected with the active layer through a second via hole of the interlayer dielectric layer, and an orthogonal projection of the second via hole on the base substrate partially overlaps with the spacer region.

In some embodiments, in the display substrate according to the embodiments of the present disclosure, the active layer includes a first channel region, a second channel region, a second contact region, a first connection region, a second connection region, a third connection region, and a fourth connection region. The second contact region is electrically connected with the second electrode, the second contact region, the first connection region, the first channel region, the second connection region, the second channel region, the third connection region, the fourth connection region and the first contact region are sequentially connected; and a combination of the first connection region, the first channel region, the second connection region, the second channel region and the third connection region is in a U-shape, the fourth connection region extends in the first direction, a width of the first contact region in the second direction is greater than a width of the fourth connection region in the second direction, and a width of the second contact region in the first direction is greater than a width of the first connection region in the first direction.

In some embodiments, in the display substrate according to the embodiments of the present disclosure, an orthogonal projection of the first channel region on the base substrate is located within the spacer region, and an orthogonal projection of the second channel region on the base substrate is located between the orthogonal projection of the first channel region on the base substrate and the orthogonal projection of the first electrode on the base substrate.

In some embodiments, in the display substrate according to the embodiments of the present disclosure, a plurality of transistors are provided, the plurality of transistors are arranged in an array on the base substrate, and the plurality of transistors include a first transistor penetrating the spacer region in the second direction and a second transistor arranged away from the first channel region of the first transistor in the first direction; and an orthogonal projection of a first electrode of the first transistor on the base substrate is located between an orthogonal projection of a second channel region of the first transistor on the base substrate and an orthogonal projection of a first channel region of the second transistor on the base substrate.

In some embodiments, in the display substrate according to the embodiments of the present disclosure, the plurality of transistors further include a third transistor arranged close to the first channel region of the first transistor in the first direction; and the same spacer region partially overlaps with an orthogonal projection of a third connection region of the first transistor on the base substrate, the orthogonal projection of the second channel region of the first transistor on the base substrate, an orthogonal projection of the second contact region of the first transistor on the base substrate, and an orthogonal projection of a first contact region of the third transistor on the base substrate separately.

In some embodiments, in the display substrate according to the embodiments of the present disclosure, in the same transistor, a minimum distance between the second contact region and the third connection region, a minimum distance between the first channel region and the second channel region, and a minimum distance between the second channel region and the first contact region are each smaller than or equal to 2.7 μm.

In some embodiments, the display substrate according to the embodiments of the present disclosure further includes an interlayer dielectric layer disposed between the active layer and the layer where the first electrode is located; the first electrode is electrically connected with the active layer through a third via hole of the interlayer dielectric layer; and an orthogonal projection of the third via hole on the base substrate partially overlaps with the orthogonal projection of the first via hole on the base substrate.

In some embodiments, in the display substrate according to the embodiments of the present disclosure, an orthogonal projection of the first channel region on the base substrate is located within the spacer region, and an orthogonal projection of the second channel region on the base substrate is located within the orthogonal projection of the first electrode on the base substrate.

In some embodiments, in the display substrate according to the embodiments of the present disclosure, an orthogonal projection of the third connection region on the base substrate, an orthogonal projection of the fourth connection region on the base substrate, and the orthogonal projection of the first contact region on the base substrate are all located within the orthogonal projection of the first electrode on the base substrate.

In some embodiments, the display substrate according to the embodiments of the present disclosure further includes an interlayer dielectric layer disposed between the active layer and the layer where the first electrode is located; the first electrode is electrically connected with the active layer through a third via hole of the interlayer dielectric layer, and an orthogonal projection of the third via hole on the base substrate is located at a side of the orthogonal projection of the first via hole on the base substrate away from the first channel region.

In some embodiments, in the display substrate according to the embodiments of the present disclosure, an orthogonal projection of the second connection region on the base substrate and the orthogonal projection of the fourth connection region on the base substrate are located at two sides of the orthogonal projection of the gate line on the base substrate respectively.

In another aspect, the embodiments of the present disclosure provide a display panel. The display panel includes the display substrate according to the embodiments of the present disclosure and an opposite substrate arranged opposite the display substrate; the display substrate or the opposite substrate includes a black matrix, the black matrix includes a first section extending in a first direction, and an orthogonal projection of a gate electrode on a base substrate and an orthogonal projection of a first electrode on the base substrate are both located within an orthogonal projection of the first section on the base substrate.

In some embodiments, in the display panel according to the embodiments of the present disclosure, a ratio of a width of the first section in a second direction to a width of a gate line in the second direction is greater than or equal to 2.6 and smaller than 3.5.

In some embodiments, in the display panel according to the embodiments of the present disclosure, an orthogonal projection of a symmetry axis of the first section extending in the first direction on the base substrate approximately coincides with an orthogonal projection of a symmetry axis of the first electrode extending in the first direction on the base substrate.

In some embodiments, in the display panel according to the embodiments of the present disclosure, on two sides of the symmetry axis of the first section extending in the first direction, the orthogonal projection of the first section on the base substrate extends by the same distance relative to an orthogonal projection of the first electrode on the base substrate.

In some embodiments, in the display panel according to the embodiments of the present disclosure, on the same side of the symmetry axis of the first section extending in the first direction, a distance between the orthogonal projection of the first section on the base substrate and the orthogonal projection of the first electrode on the base substrate in the second direction is 1.15 μm-1.5 μm.

In some embodiments, in the display panel according to the embodiments of the present disclosure, an orthogonal projection of a second electrode on the base substrate at least partially overlaps with the orthogonal projection of the first section on the base substrate.

In some embodiments, in the display panel according to the embodiments of the present disclosure, the opposite substrate further includes a spacer; the black matrix further includes a second section and a third section provided on two sides of the first section respectively, the first section includes a sub-section located between the second section and the third section, and a shape of a spliced pattern of the second section, the sub-section and the third section is the same as a shape of an orthogonal projection of the spacer on the base substrate; and the orthogonal projection of the spacer on the base substrate is located within an orthogonal projection of the spliced pattern on the base substrate, and the orthogonal projection of the second electrode on the base substrate is located within the orthogonal projection of the spliced pattern on the base substrate.

In another aspect, an embodiment of the present disclosure provides a display apparatus. The display apparatus includes the display panel according to the embodiment of the present disclosure.

### BRIEF DESCRIPTION OF FIGURES

FIG. 1 is a schematic structural diagram of a region where a transistor is located in a display substrate in the related art.

FIG. 2 is a sectional view along line I-I′ in FIG. 1.

FIG. 3 is a schematic structural diagram of a region where a transistor is located in a display substrate according to an embodiment of the present disclosure.

FIG. 4 is a sectional view along line II-II′ in FIG. 3.

FIG. 5 is another schematic structural diagram of a region where a transistor is located in a display substrate according to an embodiment of the present disclosure.

FIG. 6 is a sectional view along line III-III′ in FIG. 5.

FIG. 7 is a schematic structural diagram of a sub-pixel of a display substrate according to an embodiment of the present disclosure.

FIG. 8 is a schematic structural diagram of a transistor in the related art.

FIG. 9 is a schematic structural diagram of a transistor according to an embodiment of the present disclosure.

FIG. 10 is a schematic structural diagram of a display substrate according to an embodiment of the present disclosure.

FIG. 11 is a schematic structural diagram of a layer where a gate line is located in FIG. 10.

FIG. 12 is a schematic structural diagram of an active layer in FIG. 10.

FIG. 13 is schematic structural diagram of a layer where a first electrode is located in FIG. 10.

FIG. 14 is a schematic structural diagram of a layer where a pixel electrode is located in FIG. 10.

FIG. 15 is a schematic structural diagram of a layer where a common electrode is located in FIG. 10.

FIG. 16 is a schematic structural diagram of a region where a transistor is located in a display panel according to an embodiment of the present disclosure.

FIG. 17 is a sectional view along line IV-IV′ in FIG. 16.

FIG. 18 is another schematic structural diagram of a region where a transistor is located in a display panel according to an embodiment of the present disclosure.

FIG. 19 is a sectional view along line V-V′ in FIG. 18.

FIG. 20 is an LO image according to an embodiment of the present disclosure.

FIG. 21 is another LO image according to an embodiment of the present disclosure.

FIG. 22 shows a current-voltage curve of a transistor according to an embodiment of the present disclosure.

### DETAILED DESCRIPTION

For making objectives, technical solutions and advantages of embodiments of the present disclosure clearer, the technical solutions of the embodiments of the present disclosure will be clearly and completely described below in conjunction with the accompanying drawings in the embodiments of the present disclosure. It should be noted that a size and a shape of each figure in the drawings do not reflect a true scale, but only for illustrating contents of the present disclosure. Throughout the drawings, identical or similar reference numerals denote identical or similar elements or elements having identical or similar functions. To keep the following description of the embodiments of the present disclosure clear and concise, detailed descriptions of known functions and components are omitted in the present disclosure.

Unless otherwise defined, technical or scientific terms used herein should have ordinary meanings as understood by those of ordinary skill in the art to which the present disclosure belongs. “First”, “second” and similar words used in the description and claims of the present disclosure do not indicate any order, amount or importance, but only for distinguishing different components. “Include”, “comprise”, “involve” and other similar words indicate that elements or objects before the word include elements or objects after the word and their equivalents, without excluding other elements or objects. “Inside”, “outside”, “upper”, “lower”, etc. are only used to indicate a relative positional relation. After an absolute position of the described object changes, the relative positional relation may also change accordingly.

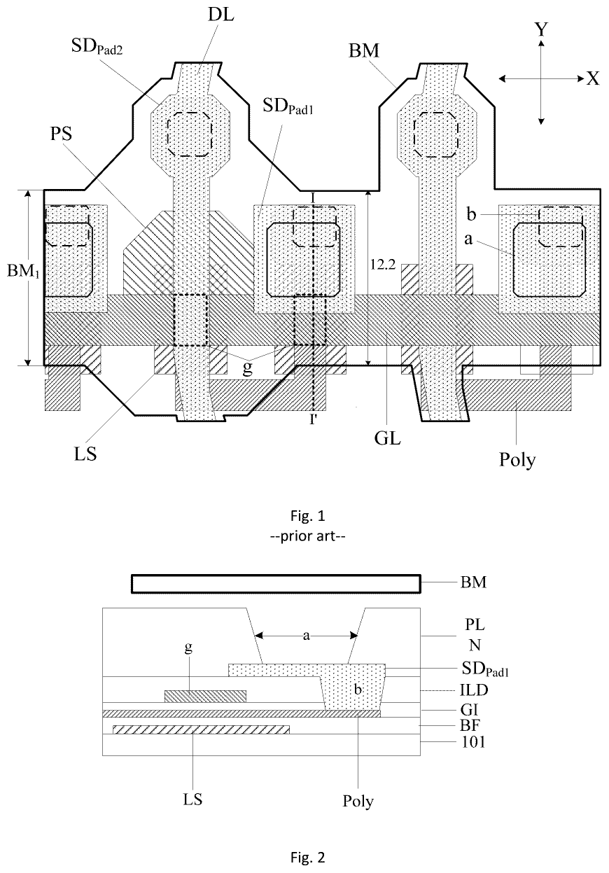

With increasing demand for transmittance of a projector, a three-dimensional (3D) printer, a virtual reality (VR) apparatus and other products, it is increasingly difficult for an existing design solution to satisfy demand of a customer, and a core factor limiting improvement in transmittance is a pixel aperture ratio. FIG. 1 shows a schematic diagram of a pixel structure in the related art. It may be seen from FIGS. 1 and 2 that a black matrix (BM) extending in a first direction X needs to completely shield a gate electrode (g) and a first electrode (SD_{Pad1}) of a transistor, and an orthogonal projection of the gate electrode (g) and an orthogonal projection of the first electrode (SD_{Pad1}) have a small overlapping region, such that a size of metal (including the gate electrode and the first electrode) that the black matrix (BM) needs to completely shield is equivalent to the sum of sizes of the gate electrode (g) and the first electrode (SD_{Pad1}) in a second direction Y. Therefore, a size of the black matrix (BM) in the second direction Y is great, which greatly influences a pixel aperture ratio.

It may be further seen from FIGS. 1 and 2 that part of a gate line (GL) whose orthogonal projection overlaps with an active layer (poly) is used as the gate electrode, and when the gate line (GL) is thin, resistance of the gate line (GL) is great, and signal voltage drop on the gate line (GL) is obvious. In order to ensure signal uniformity on the gate line (GL), a line width of the gate line (GL) should not be too narrow. Therefore, a width of the gate electrode (g) in the second direction Y cannot be further reduced. In order to ensure that the first electrode (SD_{Pad1}) and a pixel electrode on a layer where the first electrode is located are well lapped through a first via hole (a) penetrating through a planarization layer, it is necessary to ensure that the first electrode (SD_{Pad1}) completely shields the first via hole (a) of the planarization layer on the premise of considering factors such as process fluctuation and alignment accuracy. However, the first via hole (a) of the planarization layer cannot be reduced due to limitation of process capability, so the size of the first electrode (SD_{Pad1}) cannot be further reduced due to limitation of the first via hole (a) of the planarization layer. Therefore, the related art cannot adaptively reduce the size, in the second direction Y, of the black matrix (BM) extending in the first direction X by reducing the size of the gate electrode (g) and/or the first electrode (SD_{Pad1}) in the second direction Y, so as to improve the pixel aperture ratio.

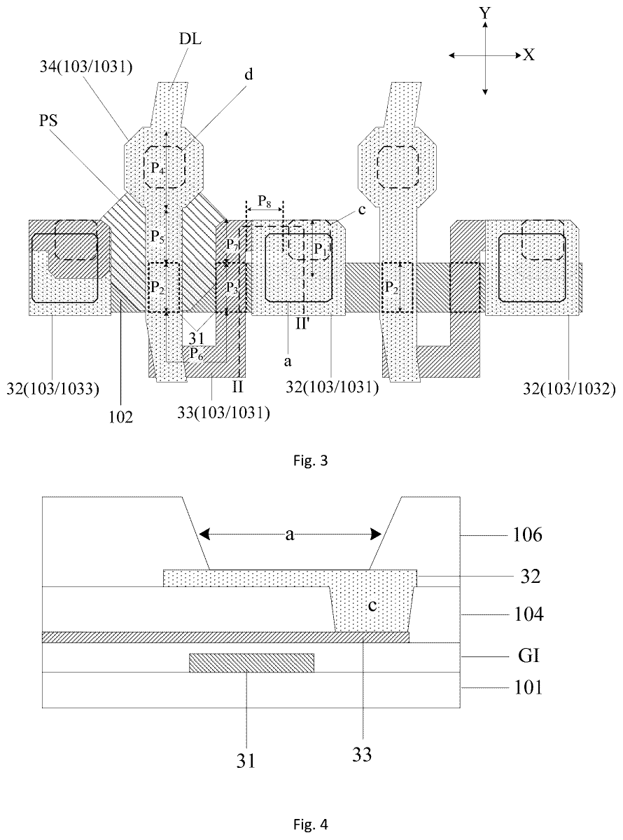

In order to improve the pixel aperture ratio, the embodiments of the present disclosure provide a display substrate. As shown in FIGS. 2 and 3, the display substrate includes:
a base substrate 101, where optionally, the base substrate 101 may be a rigid substrate made of glass, etc. or a flexible substrate made of polyimide, etc.;
a gate line (GL) 102 extending in a first direction X on the base substrate 101, where optionally, the gate line 102 may be made of metal or alloy, for example, the gate line 102 is made of a single-layer metal structure or a multi-layer metal structure composed of molybdenum, aluminum, titanium, etc., and illustratively, the gate line 102 is formed by single-layer molybdenum metal; and
a transistor 103 located on the base substrate 101; where the transistor 103 includes a gate electrode 31 and a first electrode 32 that is located at a side of a layer where the gate electrode 31 is located away from the base substrate 101, part of the gate line 102 is used as the gate electrode 31, an orthogonal projection of the gate electrode 31 on the base substrate 101 in a second direction Y is located within an orthogonal projection of the first electrode 32 on the base substrate 101 in the second direction Y, and the second direction Y intersects with the first direction X; and optionally, the first electrode 32 may be made of metal or alloy, for example, the first electrode 32 is of a single-layer metal structure or a multi-layer metal structure composed of molybdenum, aluminum, titanium, etc., and illustratively, the first electrode 32 is formed by stacked titanium metal layer/aluminum metal layer/titanium metal layer.

In the above display substrate according to the embodiments of the present disclosure, relative positions of the gate electrode 31 and the first electrode 32 in the second direction Y are adjusted, such that the orthogonal projection of the gate electrode 31 in the second direction Y is located within the orthogonal projection of the first electrode 32 in the second direction Y in the same plane parallel to the base substrate 101, that is, a size of metal including the gate electrode 31 and the first electrode 32 in the second direction Y is equal to a size of the first electrode 32. In contrast, in the related art shown in FIGS. 1 and 2, the size of the metal including the gate electrode 31 and the first electrode 32 in the second direction Y is approximately equal to the sum of sizes of the first electrode 32 and the gate electrode 31. It may be seen through comparison that the size of the metal including the gate electrode 31 and the first electrode 32 in the second direction Y in the present disclosure is small, such that a size of a black matrix configured to shield the gate electrode 31 and the first electrode 32 in the second direction Y may be reduced, which is conducive to improvement in a pixel aperture ratio.

In some embodiments, when the transistor 103 is a top-gate transistor as shown in FIG. 2, the gate electrode 31 (that is, the gate electrode g in FIG. 2) is disposed between an active layer (poly) and a layer where the first electrode (SD_{Pad1}) is located, and the first electrode (SD_{Pad1}) is electrically connected with the active layer (poly) through a via hole (b) penetrating through an interlayer dielectric layer (ILD) and a gate insulating layer (GI). Optionally, the interlayer dielectric layer (ILD) and the gate insulating layer (GI) may be made of silicon oxide, silicon nitride, silicon oxynitride, etc., and film layer structures of the interlayer dielectric layer (ILD) and the gate insulating layer (GI) may be a single-layer structure or a laminated structure, which are not limited herein.

It may be seen from FIGS. 1 and 2 that an orthogonal projection of the via hole (b) penetrating through the interlayer dielectric layer (ILD) and the gate insulating layer (GI) on the base substrate 101 is located within an orthogonal projection of the first electrode (SD_{Pad1}) on the base substrate 101. It is considered that the orthogonal projection of the gate electrode 31 of the present disclosure on the base substrate 101 in the second direction Y is also located within the orthogonal projection of the first electrode 32 (which is equivalent to the first electrode SD_{Pad1} in FIG. 2) on the base substrate 101 in the second direction Y. Therefore, in order to prevent the gate electrode 31 from being short-circuited with the first electrode 32 at the via hole (b) penetrating through the interlayer dielectric layer (ILD) and the gate insulating layer (GI), it is necessary to ensure that a distance between the gate electrode 31 and the via hole (b) penetrating through the interlayer dielectric layer (ILD) and the gate insulating layer (GI) is not too small. Moreover, in a manufacturing process of the top-gate transistor, the gate electrode (g) is also used as a layer for shielding a channel through a doping process, such that doped regions are regions on two sides of the gate line (GL), and the via hole (b) penetrating through the interlayer dielectric layer (ILD) and the gate insulating layer (GI) has to be far away from the regions on the two sides, so as to ensure that the via hole (b) does not overlap with the channel and lightly doped regions on the two sides. In a product having low resolution, a distance between the gate electrode 31 and the via hole (b) penetrating through the interlayer dielectric layer (ILD) and the gate insulating layer (GI) may be effectively ensured to be great due to sufficient wiring space. However, in a product having high resolution, wiring space is small, which is not conducive to ensuring a great distance between the gate electrode 31 and the via hole (b) penetrating through the interlayer dielectric layer (ILD) and the gate insulating layer (GI).

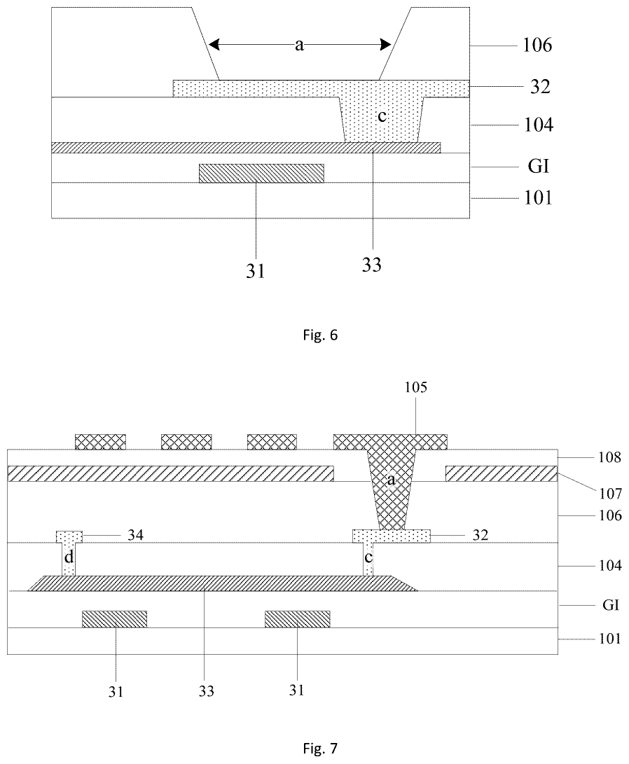

In order to adapt to the product having high resolution, the display substrate according to the embodiments of the present disclosure uses a bottom-gate transistor. Specifically, as shown in FIGS. 3-6, an active layer 33 of a transistor 103 is disposed between a layer where a gate electrode 31 is located and a layer where a first electrode 32 is located. It may be seen from FIGS. 4 and 6 that the first electrode 32 is electrically connected with the active layer 33 through a third via hole c penetrating through an interlayer dielectric layer 104. Since the gate electrode 31 is located between an interlayer dielectric layer 104 and a base substrate 101, the gate electrode 31 cannot be short-circuited with the first electrode 32 at the third via hole c penetrating through the interlayer dielectric layer 104. In this way, the third via hole c penetrating through the interlayer dielectric layer 104 may be provided close to the gate electrode 31 (which may be equivalent to a gate line 102). Further, the third via hole c of the interlayer dielectric layer 104 and the gate electrode 31 may be provided in small space, and it may be ensured that the gate electrode 31 is not short-circuited with the first electrode 32, which is conducive to application to a high-resolution product. Optionally, the active layer 33 may be a polycrystalline silicon (poly) active layer, an oxide active layer, an amorphous silicon active layer, etc., which is not limited herein.

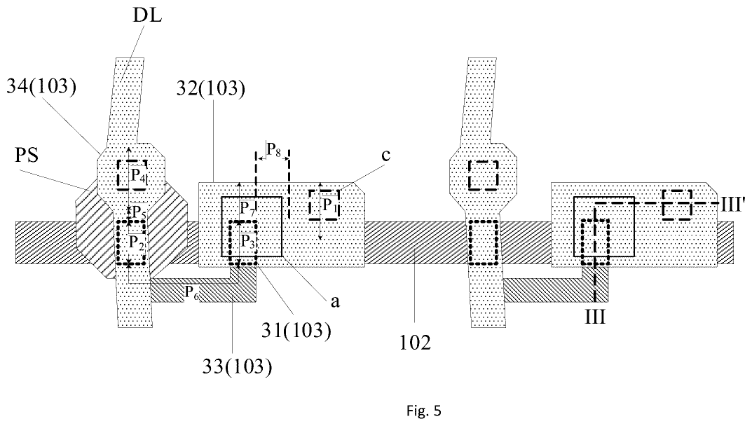

In some embodiments, in the display substrate according to the embodiments of the present disclosure, as shown in FIGS. 3 and 5, when the third via hole c of the interlayer dielectric layer 104 is provided close to the gate electrode 31, an orthogonal projection of the gate line 102 on the base substrate 101 may run through orthogonal projections of first electrodes 32 on the base substrate 101.

In some embodiments, as shown in FIGS. 3, 5 and 7, the display substrate according to the embodiments of the present disclosure may further include a pixel electrode 105 located at a side of a layer where the transistor 103 is located away from the base substrate 101, and a planarization layer 106 disposed between the layer where the transistor 103 is located and a layer where the pixel electrode 105 is located. The pixel electrode 105 is electrically connected with the first electrode 32 through a first via hole a penetrating through the planarization layer 106. An orthogonal projection of the first via hole a on the base substrate 101 and the orthogonal projection of the gate line 102 on the base substrate 101 have a first overlapping region. An area ratio of the first overlapping region to the orthogonal projection of the first via hole a on the base substrate 101 is greater than ½ and smaller than 1. In the present disclosure, the orthogonal projection of the gate line 102 on the base substrate 101 runs through the orthogonal projections of the first electrodes 32 on the base substrate 101, such that a position of the first via hole a connecting the first electrode 32 and the pixel electrode 105 may be adjusted accordingly. In this way, a major part of the orthogonal projection of the first via hole a on the base substrate 101 overlaps with the orthogonal projection of the gate line 102 on the base substrate 101 in the present disclosure. Optionally, in consideration of process fluctuation and alignment accuracy, a single side of the orthogonal projection of the first electrode 32 on the base substrate 101 may be set to extend beyond that of the orthogonal projection of the first via hole a on the base substrate 101 by a distance within 1 μm.

Optionally, in a product having high resolution (for example, a projector), space occupied by a single sub-pixel is small. In order to achieve electrical connection between the transistor 103 and the pixel electrode 105, as shown in FIG. 3, an orthogonal projection of the third via hole c configured to connect the active layer 33 and the first electrode 32 on the base substrate 101 may partially overlap with the orthogonal projection of the first via hole a configured to connect the first electrode 32 and the pixel electrode 105 on the base substrate 101. In a product having low resolution (for example, a 3D printer), space occupied by a single sub-pixel is great, such that the orthogonal projection of the third via hole c configured to connect the active layer 33 and the first electrode 32 on the base substrate 101 and the orthogonal projection of the first via hole a configured to connect the first electrode 32 and the pixel electrode 105 on the base substrate 101 may be staggered in the first direction X. For example, in FIG. 5, the orthogonal projection of the third via hole c on the base substrate 101 is located at a side of the orthogonal projection of the first via hole a on the base substrate 101 away from a first channel region P₂. In a bore trepanning solution in which the orthogonal projections overlap, a hole depth of a trepanning bore is greater than a hole depth of a single via hole, which increases difficulty of a composition process and is not conducive to formation of a pattern having a better shape at the trepanning bore. In FIG. 5, the first via hole a and the third via hole c are staggered, which can ensure pattern yield at the first via hole a and the third via hole c and reduce process difficulty.

In some embodiments, in the display substrate according to the embodiments of the present disclosure, the active layer 33 includes a first contact region p₁ electrically connected with the first electrode 32. An orthogonal projection of the first contact region p₁ on the base substrate 101 partially overlaps with the orthogonal projection of the gate line 102 on the base substrate 101. In the present disclosure, the orthogonal projection of the gate line 102 on the base substrate 101 runs through the orthogonal projections of the first electrodes 32 on the base substrate 101, such that a position of the first contact region p₁ may be adjusted accordingly. In this way, an orthogonal projection of the first contact region p₁ on the base substrate 101 partially overlaps with the orthogonal projection of the gate line 102 on the base substrate 101 in the present disclosure.

In some embodiments, in the display substrate according to the embodiments of the present disclosure, as shown in FIGS. 3 and 5, the base substrate 101 includes a spacer region PS (that is, a region configured to support a spacer). The transistor 103 further includes a second electrode 34 (that is, a second electrode SD_{Pad2} shown in FIG. 1) located in the same layer and made of the same material as the first electrode 32. An orthogonal projection of the second electrode 34 on the base substrate 101 partially overlaps with the spacer region PS. Optionally, as shown in FIGS. 3 and 5, part of a data line DL may be used as the second electrode 34, and the data line DL is widened at a position of the second electrode 34, such that the second electrode 34 may be electrically connected with the active layer 33.

The spacer is a circular-truncated-cone-shaped column on an opposite substrate, and is configured to support a liquid crystal cell gap. A design density is determined through evaluation of a supporting force of the liquid crystal cell. For example, it is designed to place a spacer corresponding to a pixel. Optionally, a pixel may include three sub-pixels: a red sub-pixel, a blue sub-pixel, and a green sub-pixel. Due to disorder of liquid crystal arrangement at a position where the spacer is located, light leakage may occur. Therefore, the position where the spacer is located has to be shielded with a black matrix, and it is ensured that a liquid crystal disorder region around the spacer is covered. The position of the second electrode 34 in the present disclosure is limited by a position of the first electrode 32. After the orthogonal projection of the gate line 102 on the base substrate 101 runs through the orthogonal projections of the first electrodes 32 on the base substrate 101, a distance between the position of a first electrode 32 and a position where a second electrode 34 (such as a second electrode SD_{Pad2} shown in FIG. 1) is located in the related art increases. When the first electrode 32 is not short-circuited with the second electrode 34, the second electrode 34 may be moved close to the gate line 102, such that the orthogonal projection of the second electrode 34 on the base substrate 101 partially overlaps with the spacer region PS. In this way, the second electrode 34 may be hidden in a black matrix region shielding the spacer, and the black matrix shielding the second electrode 34 does not need to be separately set, which is conducive to improvement in the pixel aperture ratio.

In some embodiments, in the display substrate according to the embodiments of the present disclosure, as shown in FIGS. 3 and 5, the second electrode 34 is electrically connected with the active layer 33 through a second via hole d of the interlayer dielectric layer 104. An orthogonal projection of the second via hole d on the base substrate 101 partially overlaps with the spacer region PS. In the present disclosure, the orthogonal projection of the second electrode 34 on the base substrate 101 is set to partially overlap with the spacer region PS, such that a position of the second via hole d may be adjusted accordingly. In this way, the orthogonal projection of the second via hole d on the base substrate 101 partially overlaps with the spacer region PS in the present disclosure.

In some embodiments, in the display substrate according to the embodiments of the present disclosure, as shown in FIGS. 3 and 5, the active layer 33 may further include a first channel region P₂, a second channel region P₃, a second contact region P₄, a first connection region P₅, a second connection region P₆, a third connection region P₇, and a fourth connection region P₈. The second contact region P₄ is electrically connected with the second electrode 34. The second contact region P₄, the first connection region P₅, the first channel region P₂, the second connection region P₆, the second channel region P₃, the third connection region P₇, the fourth connection region P₈ and the first contact region P₁ are sequentially connected. A combination of the first connection region P₅, the first channel region P₂, the second connection region P₆, the second channel region P₃ and the third connection region P₇ is in a U-shape. The fourth connection region P₈ extends away from the U-shape, and specifically, may extend in the first direction X. A width of the first contact region P₁ in the second direction Y is greater than a width of the fourth connection region P₈ in the second direction Y. A width of the second contact region P₄ in the first direction X is greater than a width of the first connection region P₅ in the first direction X. An orthogonal projection of the second connection region P₆ on the base substrate 101 and an orthogonal projection of the fourth connection region P₈ on the base substrate 101 are located at two sides of the orthogonal projection of the gate line 102 on the base substrate 101 respectively.

It may be seen from FIG. 1 that a pattern of the active layer (poly) in the related art is approximately U-shaped. In the present disclosure, transverse wiring (for example, the fourth connection region P₈) of the active layer 33 is added on the basis of a U-shaped structure of the active layer 33, so as to drive the third via hole c in the first contact region P₁ to bypass the second channel region P₃. In this way, distance demand between the third via hole c in the first contact region P₁ and the gate line 102 may be reduced. The third via hole c in the first contact region P₁ moves close to the gate line 102, and the third via hole c in the first contact region P₁ avoids the second channel region P₃ in the second direction Y, such that the third via hole c in the first contact region P₁ moves close to the gate line 102 without overlapping with a channel, and the first electrode 32 electrically connected with the third via hole c may further move close to the gate line 102. Accordingly, the first via hole A connecting the first electrode 32 and the pixel electrode 105 and the first electrode 32 move close to the gate line 102 together. Finally, the orthogonal projection of the gate line 102 on the base substrate 101 in the present disclosure runs through the orthogonal projections of the first electrodes 32 on the base substrate 101. A major part of the orthogonal projection of the first via hole a on the base substrate 101 overlaps with the orthogonal projection of the gate line 102 on the base substrate 101, so that the black matrix extending in the first direction X only needs to shield the orthogonal projection of the first electrode 32 on the base substrate 101. In this way, a size, in the second direction Y, of the black matrix extending in the first direction X may be greatly reduced, and further the pixel aperture ratio is effectively improved.

It should be understood that the gate electrodes 31 corresponding to a position of the first channel region P₂ and a position of the second channel region P₃ are both the gate electrodes 31 of the transistor 103, so the transistor 103 in the present disclosure is a double-gate transistor. Compared with a single-gate transistor having one gate electrode, the double-gate transistor may strengthen control of the gate electrode 31 on the channel, increase the on-state current of the transistor 103, reduce the off-state current of the transistor 103, suppress a warping effect, reduce threshold voltage and sub-threshold slope, and improve driving capability of the transistor 103.

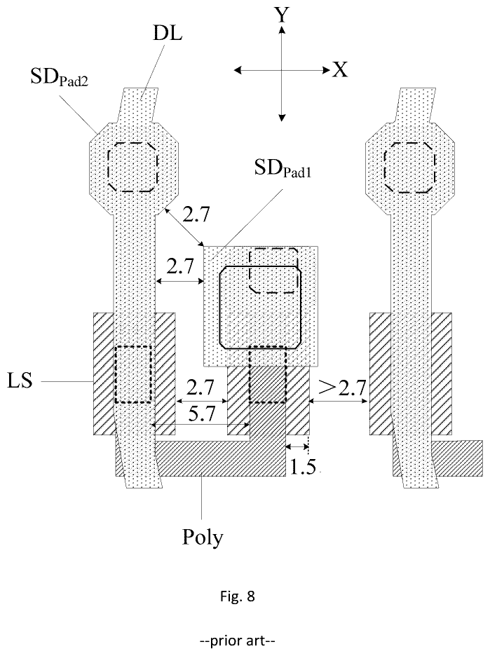

It should be noted that, in the solution in which a top-gate transistor shields backlight with a light shielding pattern as shown in FIG. 8, in consideration of a general process margin, a minimum distance between light shielding patterns LS has to be reserved about 2.7 μm, and in consideration of an illumination characteristic, a single side of the light shielding pattern LS has to extend beyond that of a channel region shielded by the light shielding pattern by least 1.5 μm. In this way, a minimum distance between the first channel region P₂ and the second channel region P₃ is 5.7 μm. A distance between the light shielding patterns LS may be appropriately increased according to a size of a pixel. For example, when resolution is small and the size of the pixel is great, a distance between two adjacent light shielding patterns LS may be appropriately increased to 3.0 μm, and remaining space is reserved for a distance between two adjacent transistors 103. It is ensured that the distance between the two adjacent transistors 103 is greater than a general process margin 2.7 μm. In order to avoid a short circuit between the first electrode 32 and the second electrode 34, it is necessary to ensure that a minimum distance between the first electrode and the second electrode is 2.7 μm, which is the general process margin. Meanwhile, the second electrode 34 moves towards the gate line 102, such that an area of the second electrode 34 entering a pixel aperture region may be reduced. Optionally, a minimum distance between the second contact region P₄ and the third connection region P₇ corresponding to the second electrode 34 satisfies the general process margin 2.7 μm. The above values may be appropriately decreased or increased according to process capability and pixel size.

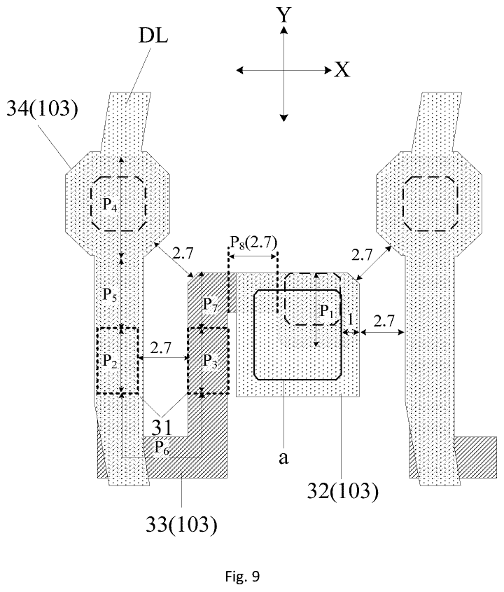

As shown in FIG. 9, the bottom-gate transistor 103 according to the present disclosure may shield backlight with the gate electrode 31, and may reduce an occurrence probability of a photo-induced leakage phenomenon of the channel without additionally setting the light shielding pattern LS, such that a distance between the first channel region P₂ and the second channel region P₃ may be decreased to the general process margin 2.7 μm, which is much smaller than a minimum distance 5.7 μm between the first channel region P₂ and the second channel region P₃ in the related art. In this way, the present disclosure may reserve more space allowing the active layer 33 to transversely extend to bypass the channel. Optionally, the minimum distance between the first contact region P₁ and the second channel region P₃ is the general process margin 2.7 μm, and the distance between the first electrode 32 and the second electrode 31 in an adjacent sub-pixel is greater than or equal to 2.7 μm, such that the first electrode 32 is prevented from being short-circuited with the second electrode 31 in the adjacent sub-pixel. The current conventional process capability of 2.7 μm may fluctuate according to different processes, and may be further reduced according to improvement in process accuracy, for example, within 2.7 μm-1 μm.

In some embodiments, a heavily-doped mask (such as, an N+ doping mask) may be configured to conduct doping on the first contact region P₁ and the second contact region P₂, and a lightly doped drain (LDD) doping mask may be configured to conduct light doping on adjacent regions on two ends of the first channel region P₂ and adjacent regions on two ends of the second channel region P₃, such that channel doping is not influenced.

In some embodiments, in the display substrate according to the embodiments of the present disclosure, as shown in FIG. 3, an orthogonal projection of the first channel region P₂ on the base substrate 101 is located within the spacer region PS. An orthogonal projection of the second channel region P₃ on the base substrate 101 is located between the orthogonal projection of the first channel region P₂ on the base substrate 101 and the orthogonal projection of the first electrode 32 on the base substrate 101. In this way, the first electrode 32 may avoid the second channel region P₃ (which is equivalent to the position of the gate electrode 31) in the second direction Y, such that the size, in the second direction Y, of the black matrix extending in the first direction X is reduced.

In some embodiments, in the display substrate according to the embodiments of the present disclosure, as shown in FIGS. 3 and 5, a plurality of transistors 103 are provided. The plurality of transistors 103 are arranged in an array on the base substrate 101. The plurality of transistors 103 include a first transistor 1031 penetrating the spacer region PS in the second direction Y and a second transistor 1032 arranged away from a first channel region P₂ of the first transistor 1031 in the first direction X. Compared with the related art, in the present disclosure, after adjusting the position of the first electrode 32 and a shape of the active layer 33, an orthogonal projection of an first electrode 32 of the first transistor 1031 on the base substrate 101 may be located between an orthogonal projection of a second channel region P₃ of the first transistor 1031 on the base substrate 101 and an orthogonal projection of a first channel region P₂ of the second transistor 1032 on the base substrate 101.

In some embodiments, in the display substrate according to the embodiments of the present disclosure, as shown in FIGS. 3 and 5, the plurality of transistors 103 may further include a third transistor 1033 arranged close to the first channel region P₂ of the first transistor 1031 in the first direction X. Compared with the related art, in the present disclosure, after adjusting the position of the first electrode 32 and the shape of the active layer 33, the same spacer region PS may partially overlap with an orthogonal projection of a third connection region P₇ of the first transistor 1031 on the base substrate 101, the orthogonal projection of the second channel region P₃ of the first transistor 1031 on the base substrate 101, an orthogonal projection of the second contact region P₄ of the first transistor 1031 on the base substrate 101, and an orthogonal projection of a first contact P₁ of the third transistor 1033 on the base substrate 101 separately.

In some embodiments, in the display substrate according to the embodiments of the present disclosure, in order to reserve transverse wiring space of the active layer 33 as much as possible, a minimum distance between the second contact region P₄ and the third connection region P₇, a minimum distance between the first channel region P₂ and the second channel region P₃, and a minimum distance between the first contact P₁ and the second channel region P₃ (which is equivalent to a length of the fourth connection region P₈ in the first direction X) may each be set to be smaller than or equal to 2.7 82 m in the same transistor 103, and for example, may be 1 μm-2.7 μm.

In some embodiments, in the display substrate according to the embodiments of the present disclosure, as shown in FIG. 5, an orthogonal projection of the first channel region P₂ on the base substrate 101 is located within the spacer region PS. An orthogonal projection of the second channel region P₃ on the base substrate 101 is located within the orthogonal projection of the first electrode 3₂ on the base substrate 101. In this way, the first electrode 32 may completely cover the second channel region P₃ (which is equivalent to the position of the gate electrode 31) in the second direction X, such that the size, in the second direction Y, of the black matrix extending in the first direction X is reduced. In this case, with reference to FIG. 5, an orthogonal projection of the third connection region P₇ on the base substrate 101, an orthogonal projection of the fourth connection region P₈ on the base substrate 101, and the orthogonal projection of the first contact P₁ on the base substrate 101 may be all located within the orthogonal projection of the first electrode 32 on the base substrate 101.

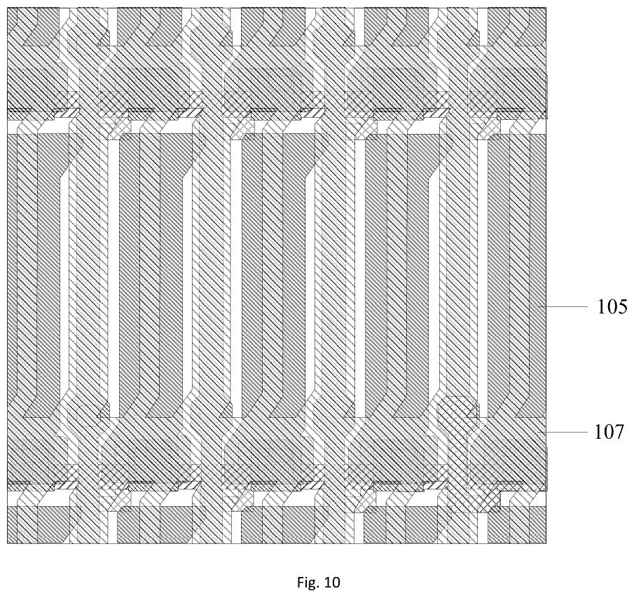

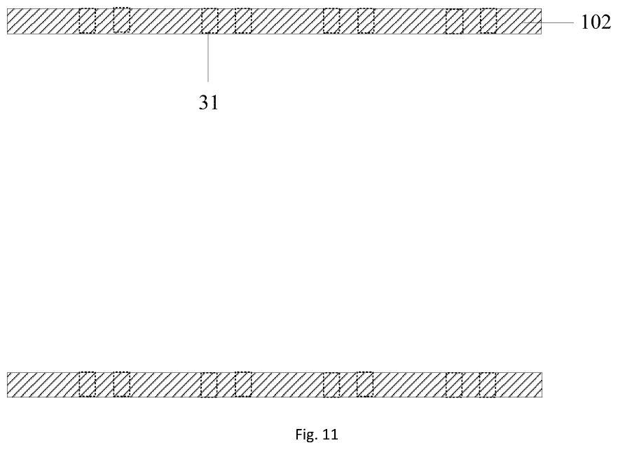

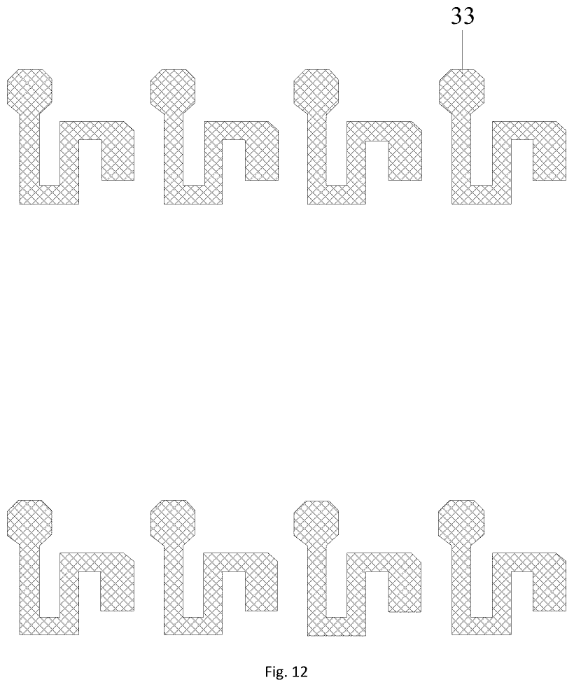

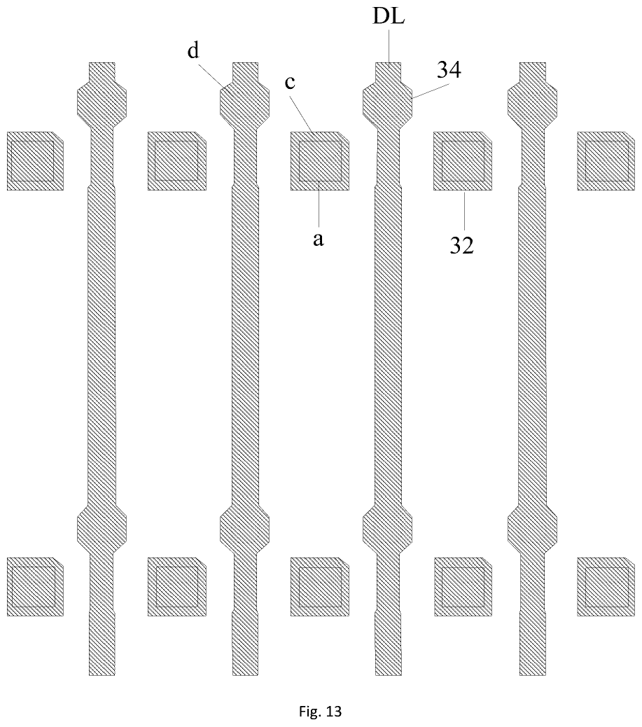

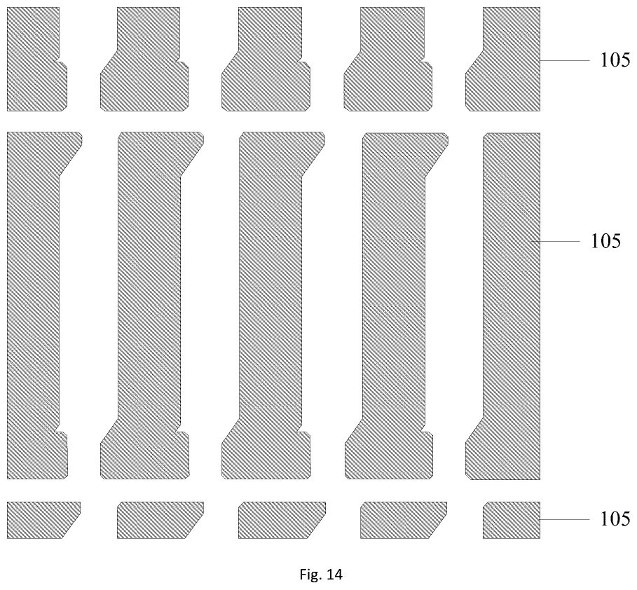

In some embodiments, as shown in FIG. 7, the display substrate according to the embodiments of the present disclosure further includes a common electrode 107 disposed between the layer where the pixel electrode 105 is located and the planarization layer 106. In some embodiments, as shown in FIG. 7, the pixel electrode 105 is a slit electrode, and the common electrode 107 is a block electrode. In some other embodiments, as shown in FIGS. 10-15, the common electrode 107 may further be located on the layer where the pixel electrode 105 is located, the common electrode 107 is a slit electrode, and the pixel electrode 105 is a block electrode. Certainly, in some embodiments, the common electrode 107 may further be located on the opposite substrate. Alternatively, the common electrode 107 and the pixel electrode 105 are arranged in the same layer on the display substrate, and the common electrode 107 and the pixel electrode 105 are both of a comb structure. A comb tooth part of the common electrode 107 intersects with a comb tooth part of the pixel electrode 105. Optionally, materials of the pixel electrode 105 and the common electrode 107 include, but are not limited to, transparent conductive materials such as indium tin oxide (ITO) and indium zinc oxide (IZO).

In addition, as shown in FIG. 7, the display substrate according to the embodiments of the present disclosure may further include an inorganic insulating layer 108 disposed between a layer where the common electrode 107 is located and the layer where the pixel electrode 105 is located. Optionally, the inorganic insulating layer 108 may be made of silicon oxide, silicon nitride, silicon oxynitride, etc. A film layer structure of the inorganic insulating layer 108 may be a single-layer structure or a laminated structure, which is not limited herein. Other essential components of the display substrate should be understood by those of ordinary skill in the art, which will not be repeated herein and should not limit the present disclosure.

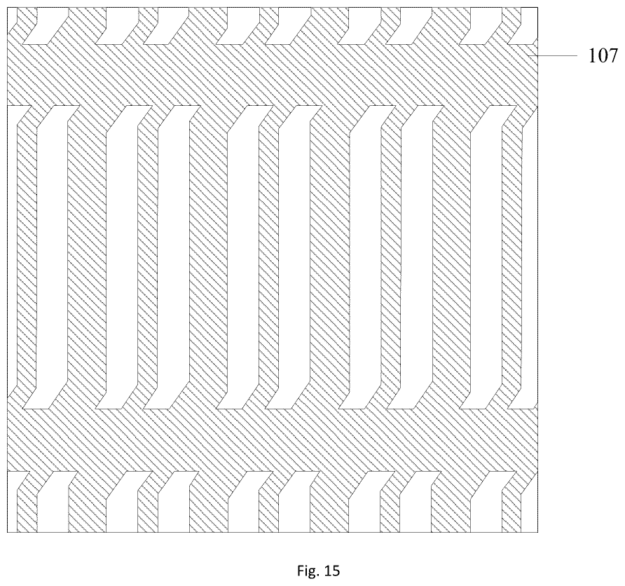

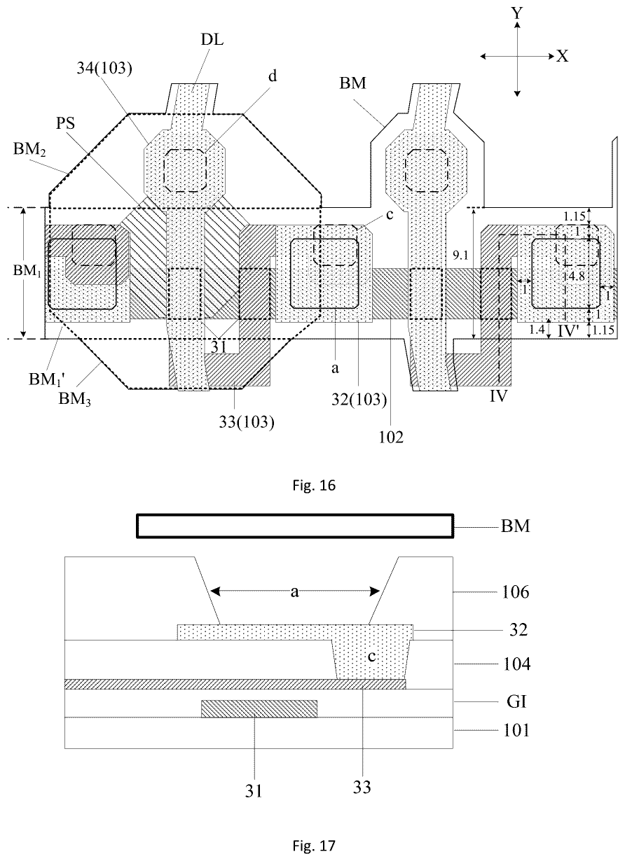

In another aspect, the embodiments of the present disclosure provide a display panel. As shown in FIGS. 16-19, the display panel includes the display substrate 001 according to the embodiments of the present disclosure and an opposite substrate 002 arranged opposite the display substrate 001. The display substrate 001 or the opposite substrate 002 includes a black matrix BM. The black matrix BM includes a first section BM₁ extending in a first direction X. An orthogonal projection of a gate electrode 31 on a base substrate 101 and an orthogonal projection of a first electrode 32 on the base substrate 101 are both located within an orthogonal projection of the first section BM₁ on the base substrate 101.

Compared with the related art, in the present disclosure, the first electrode 32 is moved close to a gate line 102 until the orthogonal projection of the gate line 102 on the base substrate 101 runs through the orthogonal projections of the first electrodes 32 on the base substrate 101, such that a size of the first section BM₁ in a second direction Y is equal to or slightly greater than a size of the first electrode 32 in the second direction Y. That is, the first electrode 32 and the gate line 102 may be shielded simultaneously by the first section BM₁, which is conducive to improvement in a pixel aperture ratio. In some embodiments, a ratio of a width of the first section BM₁ in the second direction Y to a width of the gate line 102 in the second direction Y is 3.5 in the related art; and a ratio of a width of the first section BM₁ in the second direction Y to a width of the gate line 102 in the second direction Y is greater than or equal to 2.6 and smaller than 3.5 in the present disclosure, and for example, is 2.6, 3, etc.

FIG. 16 shows design parameters of the present disclosure. As shown in FIG. 16, an aperture of a first via hole a is 4.8 μm. In consideration of process fluctuation and alignment accuracy, a single side of the orthogonal projection of the first electrode 32 on the base substrate 101 has to extend beyond that of an orthogonal projection of the first via hole a on the base substrate 101 by 1 μm. Then, in consideration of reflection of the first electrode 32, a single side of the orthogonal projection of the first section BM₁ on the base substrate 101 has to extend beyond that of the orthogonal projection of the first electrode 32 on the base substrate 101 by 1.15 um. In this way, the width of the first section BM₁ in the second direction Y is 4.8+1.0*2+1.15*2=9.1 (μm), which is greatly reduced compared with the width 12.2 μm of the first section BM₁ in the second direction Y in the related art as shown in FIG. 1, such that a pixel aperture ratio can be greatly improved. Optionally, in consideration of an illumination characteristic, a single side of the orthogonal projection of the first section BM₁ on the base substrate 101 extends beyond that of the orthogonal projection of the gate electrode 102 on the base substrate 101 by 1.4 μm, and the single side of the orthogonal projection of the first section BM₁ on the base substrate 101 extends beyond that of the orthogonal projection of the first electrode 32 on the base substrate 101 by 1.15 μm, such that a single side of the orthogonal projection of the first electrode 32 on the base substrate 101 extends beyond that of the orthogonal projection of the gate electrode 102 on the base substrate 101 by at least 1.4-1.15=0.25 (μm).

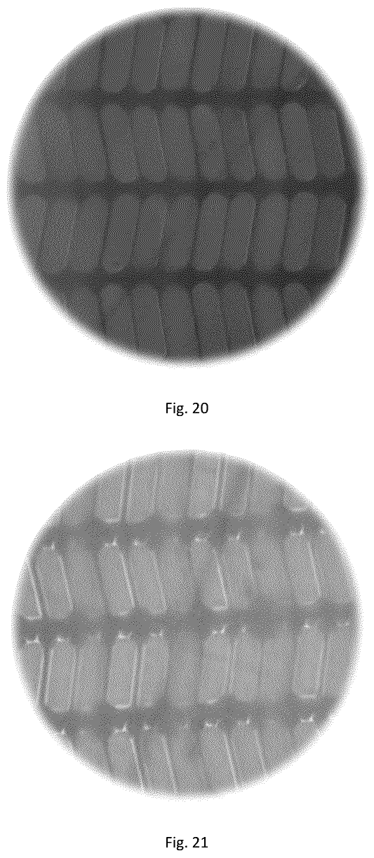

Illustratively, the present disclosure further provides an L0 image when the single side of the orthogonal projection of the first section BM₁ on the base substrate 101 extends beyond that of the orthogonal projection of the first electrode 32 on the base substrate 101 by 1.15 μm, as shown in FIG. 20. In addition, the present disclosure further provides an L0 image when the single side of the orthogonal projection of the first section BM₁ on the base substrate 101 extends beyond that of the orthogonal projection of the first electrode 32 on the base substrate 101 by a distance smaller than 1.15 μm, as shown in FIG. 21. Through comparison between FIG. 20 and FIG. 21, it may be seen that the image shown in FIG. 20 is clearer and has no light leakage, while the image in FIG. 21 is fuzzier and has obvious light leakage.

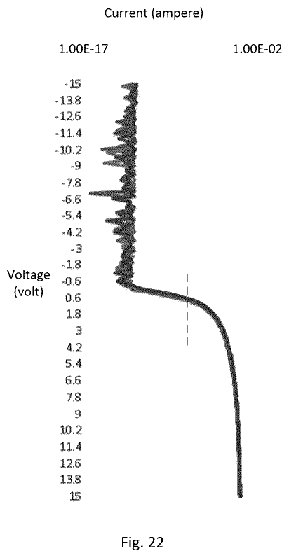

Optionally, the present disclosure further provides a current-voltage curve of a transistor 103 when the single side of the orthogonal projection of the first section BM₁ on the base substrate 101 extends beyond that of the orthogonal projection of the gate electrode 102 on the base substrate 101 by 1.4 μm, as shown in FIG. 22. It may be seen from FIG. 22 that all off-state currents of the transistor 103 are smaller under voltage of −0.6 V or below, which indicates that illumination does not cause large leakage current, so the present disclosure can satisfy good illumination characteristics.

It should be noted that what are described above only illustrate that the technical solution of the present disclosure may reduce the width of the first section BM₁ in the second direction Y. In specific implementation, the above parameters may be adjusted according to a size of a pixel and process capability, which are not specifically limited herein. In addition, as shown in FIGS. 17 and 19, a first via hole a in the present disclosure is a gradually-changing-aperture hole wider in upper part and narrower in lower part. An aperture of the first via hole a in the present disclosure is an aperture of a port of the first via hole a in contact with the first electrode 32. In some embodiments, the first via hole a may also be a cylindrical hole constant in aperture. In this case, the aperture of the first via hole a is a diameter of any section perpendicular to an extension direction of the first via hole a.

In some embodiments, in the display panel according to the embodiments of the present disclosure, in order to enable the first section BM₁ to completely shield the first electrode 32 and ensure a small size of the first section BM₁, an orthogonal projection of a symmetry axis of the first section BM₁ extending in the first direction X on the base substrate 101 may be set to approximately coincide with an orthogonal projection of a symmetry axis of the first electrode 32 extending in the first direction X on the base substrate 101. That is, on two sides of the symmetry axis of the first section BM₁ extending in the first direction X, the orthogonal projection of the first section BM₁ on the base substrate 101 extends by the same distance relative to an orthogonal projection of the first electrode 32 on the base substrate 101. Optionally, in order to improve a pixel aperture ratio and prevent the first electrode 32 from reflecting light so as to improve contrast, in the present disclosure, on the same side of the symmetry axis of the first section BM₁ extending in the first direction X, a distance between the orthogonal projection of the first section BM₁ on the base substrate 101 and the orthogonal projection of the first electrode 32 on the base substrate 101 in the second direction Y has to be kept within 1.15 μm-1.5 μm. That is, the single side of the orthogonal projection of the first section BM₁ on the base substrate 101 extends beyond that of the orthogonal projection of the first electrode 32 on the base substrate 101 by 1.15 μm-1.5 μm.

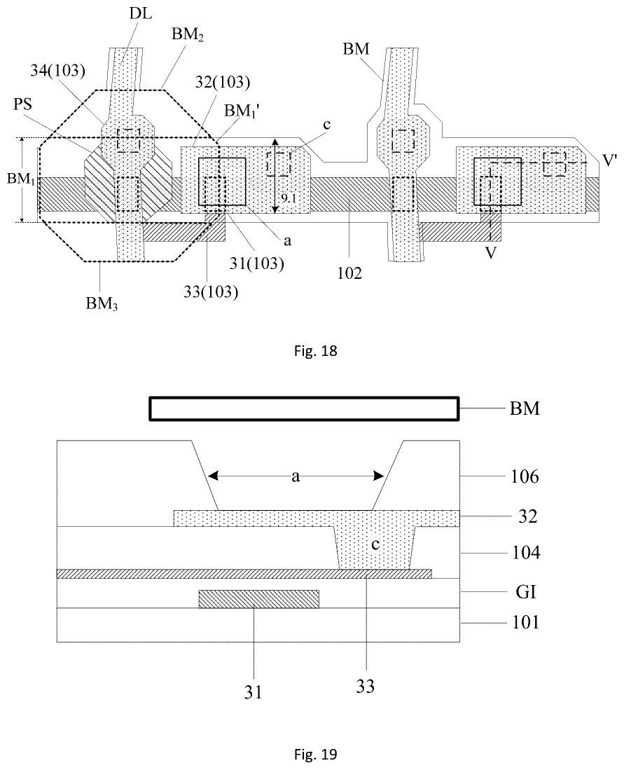

In some embodiments, in the display panel according to the embodiments of the present disclosure, as shown in FIGS. 16 and 18, an orthogonal projection of a second electrode 34 on the base substrate 101 at least partially overlaps with the orthogonal projection of the first section BM₁ on the base substrate 101. In this way, a pixel aperture region occupied by the second electrode 34 in the second direction Y is minimized, and further the pixel aperture ratio is improved.

In some embodiments, in the display panel according to the embodiments of the present disclosure, the opposite substrate 002 may further include a spacer (not shown in the figure). As shown in FIGS. 16-18, the black matrix BM may further include a second section BM₂ and a third section BM₃ provided at two sides of the first section BM₁ respectively. The first section BM₁ includes a sub-section BM₁′ located between the second section BM₂ and the third section BM₃. A shape of a spliced pattern of the second section BM₂, the sub-section BM₁′ and the third section BM₃ is the same as a shape of an orthogonal projection (that is, a spacer region PS) of the spacer on the base substrate 101. The orthogonal projection (that is, the spacer region PS) of the spacer on the base substrate 101 is located within an orthogonal projection of the spliced pattern on the base substrate 101. The orthogonal projection of the second electrode 34 on the base substrate 101 is located within the orthogonal projection of the spliced pattern on the base substrate 101. In this way, a region where the second electrode 34 is located is hidden in a region where the spliced pattern shielding the spacer region PS is located, and the black matrix shielding the second electrode 34 does not need to be separately set, which is conducive to improvement in the pixel aperture ratio. Optionally, a center of the orthogonal projection (that is, the spacer region PS) of the spacer on the base substrate 101 coincides with a center of the orthogonal projection of the spliced pattern on the base substrate 101.

In some embodiments, the display panel according to the embodiments of the present disclosure may further include a liquid crystal layer located between the display substrate 001 and the opposite substrate 002, a sealant surrounding the liquid crystal layer between the display substrate and the opposite substrate, a first alignment layer located at a side of the display substrate close to the liquid crystal layer, a second alignment layer located at a side of the opposite substrate close to the liquid crystal layer, a first polarizer located at a side of the display substrate away from the liquid crystal layer, and a second polarizer located at a side of the opposite substrate away from the liquid crystal layer. A light transmission axis of the first polarizer is perpendicular to a light transmission axis of the second polarizer. Other essential components of the display substrate should be understood by those of ordinary skill in the art, which will not be repeated herein and should not limit the present disclosure.

Based on the same inventive concept, the embodiments of the present disclosure further provide a display apparatus, which includes the display panel according to the embodiments of the present disclosure. A problem solving principle of the display apparatus is similar to a problem solving principle of the display panel, so reference may be made to implementation of the display panel for implementation of the display apparatus according to the embodiment of the present disclosure, which will not be repeated herein.

In some embodiments, the display apparatus according to the embodiments of the present disclosure may further include a backlight module and a display panel arranged at a light emitting side of the backlight module. The backlight module may be a direct-lit backlight module or an edge-lit backlight module. Optionally, the edge-lit backlight module may include a light bar, and a reflective sheet, a light guide plate, a diffusion sheet, a prism group, etc. that are stacked. The light bar is located at a side of the light guide plate in a thickness direction. The direct-lit backlight module may include a matrix light source, and a reflective sheet, a diffusion plate, a brightness enhancement film, etc. that are stacked on a light emitting side of the matrix light source. The reflective sheet includes openings arranged directly facing a position of each lamp bead in the matrix light source. The light beads in the light bar and the light beads in the matrix light source may be light emitting diodes (LEDs), such as mini LEDs and micro LEDs. Like organic light emitting diodes (OLEDs), submillimeter-scale or even micron-scale micro light emitting diodes belong to self-luminous devices. Like the organic light emitting diodes, the submillimeter-scale or even micron-scale micro light emitting diodes have a series of advantages, such as high brightness, ultra-low delay and a super-large viewing angle. Moreover, an inorganic light emitting diode emits light on the basis of a metal semiconductor having more stable properties and lower resistance, such that the inorganic light emitting diode has lower power consumption, higher resistance to high and low temperature and longer service life than an organic light emitting diode that emits light on the basis of organic substances. When a micro light emitting diode is used as a backlight source, a more precise dynamic backlight effect can be achieved, brightness and contrast of a screen can be effectively improved, and meanwhile, a glare phenomenon caused by traditional dynamic backlight between bright and dark regions of the screen can be avoided, which optimizes visual experience.

In some embodiments, the display apparatus according to the embodiments of the present disclosure may be any product or component with a display function, such as a projector, a 3D printer, a virtual reality apparatus, a mobile phone, a tablet computer, a television, a display, a notebook computer, a digital photo frame, a navigator, a smart watch, a fitness wristband, and a personal digital assistant. Optionally, the display apparatus according to the embodiments of the present disclosure may include, but is not limited to, a radio frequency unit, a network module, an audio output-input unit, a sensor, a display unit, a user input unit, an interface unit, a control chip and other components. Optionally, the control chip is a central processing unit, a digital signal processor, a system-on-a-chip (SoC), etc. For example, the control chip may further include a memory, a power module, etc., and power supply and signal input and output functions are achieved through additionally arranged wires and signal lines. For example, the control chip may further include a hardware circuit and a computer executable code. The hardware circuit may include a conventional very large scale integration (VLSI) circuit or a gate array and existing semiconductors such as a logic chip and a transistor or other discrete elements. The hardware circuit may further include a field programmable gate array, a programmable array logic, a programmable logic apparatus, etc. Moreover, those skilled in the art can understand that the above structure does not limit the display apparatus according to the embodiments of the present disclosure. That is, the display apparatus according to the embodiments of the present disclosure may include more or less components, or combine some components, or have different component arrangements.

Although the present disclosure describes preferred embodiments, it should be understood that those skilled in the art can make various modifications and variations to the embodiments of the present disclosure without departing from the spirit and scope of the embodiments of the present disclosure. In this way, if these modifications and variations of the embodiments of the present disclosure fall within the scope of the claims of the present disclosure and their equivalent technologies, the present disclosure is also intended to involve these modifications and variations.

1-26. (cancelled)

27. A display substrate, comprising:
a base substrate;
a gate line extending in a first direction on the base substrate; and
a transistor located on the base substrate, wherein the transistor comprises a gate electrode and a first electrode that is located at a side of a layer where the gate electrode is located away from the base substrate, part of the gate line is used as the gate electrode, an orthogonal projection of the gate electrode on the base substrate in a second direction is located within an orthogonal projection of the first electrode on the base substrate in the second direction, and the second direction intersects with the first direction.

28. The display substrate according to claim 27, wherein the transistor further comprises an active layer, and the active layer is disposed between the layer where the gate electrode is located and a layer where the first electrode is located; and
wherein when a plurality first electrodes are provided, an orthogonal projection of the gate line on the base substrate runs through orthogonal projections of the first electrodes on the base substrate.

29. The display substrate according to claim 28, further comprising a pixel electrode located at a side of a layer where the transistor is located away from the base substrate, and a planarization layer disposed between the layer where the transistor is located and a layer where the pixel electrode is located, wherein
the pixel electrode is electrically connected with the first electrode through a first via hole penetrating through the planarization layer, an orthogonal projection of the first via hole on the base substrate and the orthogonal projection of the gate line on the base substrate have a first overlapping region, and an area ratio of the first overlapping region to the orthogonal projection of the first via hole on the base substrate is greater than ½ and smaller than 1; and wherein a single side of the orthogonal projection of the first electrode on the base substrate extends beyond that of the orthogonal projection of the first via hole on the base substrate by a distance within 1 μm.

30. The display substrate according to claim 29, wherein the active layer comprises a first contact region electrically connected with the first electrode, and an orthogonal projection of the first contact region on the base substrate partially overlaps with the orthogonal projection of the gate line on the base substrate.

31. The display substrate according to claim 29, wherein the base substrate comprises a spacer region, the transistor further comprises a second electrode located in a same layer and made of a same material as the first electrode, and an orthogonal projection of the second electrode on the base substrate partially overlaps with the spacer region.

32. The display substrate according to claim 31, further comprising an interlayer dielectric layer disposed between the active layer and a layer where the second electrode is located, wherein the second electrode is electrically connected with the active layer through a second via hole of the interlayer dielectric layer, and an orthogonal projection of the second via hole on the base substrate partially overlaps with the spacer region.

33. The display substrate according to claim 31, wherein the active layer comprises a first channel region, a second channel region, a second contact region, a first connection region, a second connection region, a third connection region, and a fourth connection region, wherein the second contact region is electrically connected with the second electrode, and the second contact region, the first connection region, the first channel region, the second connection region, the second channel region, the third connection region, the fourth connection region and the first contact region are sequentially connected; and a combination of the first connection region, the first channel region, the second connection region, the second channel region, and the third connection region is in a U-shape, the fourth connection region extends in the first direction, a width of the first contact region in the second direction is greater than a width of the fourth connection region in the second direction, and a width of the second contact region in the first direction is greater than a width of the first connection region in the first direction.

34. The display substrate according to claim 33, wherein an orthogonal projection of the first channel region on the base substrate is located within the spacer region, and an orthogonal projection of the second channel region on the base substrate is located between the orthogonal projection of the first channel region on the base substrate and the orthogonal projection of the first electrode on the base substrate;
wherein a plurality of transistors are provided, the plurality of transistors are arranged in an array on the base substrate, and the plurality of transistors comprise a first transistor penetrating the spacer region in the second direction and a second transistor arranged away from the first channel region of the first transistor in the first direction; and
an orthogonal projection of a first electrode of the first transistor on the base substrate is located between an orthogonal projection of a second channel region of the first transistor on the base substrate and an orthogonal projection of a first channel region of the second transistor on the base substrate.

35. The display substrate according to claim 34, wherein the plurality of transistors further comprise a third transistor arranged close to the first channel region of the first transistor in the first direction; and
a same spacer region partially overlaps with an orthogonal projection of a third connection region of the first transistor on the base substrate, the orthogonal projection of the second channel region of the first transistor on the base substrate, an orthogonal projection of the second contact region of the first transistor on the base substrate, and an orthogonal projection of a first contact region of the third transistor on the base substrate separately.

36. The display substrate according to claim 34, wherein in a same transistor, a minimum distance between the second contact region and the third connection region, a minimum distance between the first channel region and the second channel region, and a minimum distance between the second channel region and the first contact region are each smaller than or equal to 2.7 μm.

37. The display substrate according to claim 33, further comprising an interlayer dielectric layer disposed between the active layer and the layer where the first electrode is located, wherein the first electrode is electrically connected with the active layer through a third via hole of the interlayer dielectric layer; and an orthogonal projection of the third via hole on the base substrate partially overlaps with the orthogonal projection of the first via hole on the base substrate.

38. The display substrate according to claim 33, wherein an orthogonal projection of the first channel region on the base substrate is located within the spacer region, and an orthogonal projection of the second channel region on the base substrate is located within the orthogonal projection of the first electrode on the base substrate; and
wherein an orthogonal projection of the third connection region on the base substrate, an orthogonal projection of the fourth connection region on the base substrate, and the orthogonal projection of the first contact region on the base substrate are all located within the orthogonal projection of the first electrode on the base substrate.

39. The display substrate according to claim 33, further comprising an interlayer dielectric layer disposed between the active layer and the layer where the first electrode is located, wherein the first electrode is electrically connected with the active layer through a third via hole of the interlayer dielectric layer; and an orthogonal projection of the third via hole on the base substrate is located at a side of the orthogonal projection of the first via hole on the base substrate away from the first channel region.

40. The display substrate according to claim 33, wherein an orthogonal projection of the second connection region on the base substrate and the orthogonal projection of the fourth connection region on the base substrate are located at two sides of the orthogonal projection of the gate line on the base substrate, respectively.

41. A display panel, comprising a display substrate and an opposite substrate arranged opposite the display substrate;
wherein the display substrate comprises:
a base substrate;
a gate line extending in a first direction on the base substrate; and
a transistor located on the base substrate, wherein the transistor comprises a gate electrode and a first electrode that is located at a side of a layer where the gate electrode is located away from the base substrate, part of the gate line is used as the gate electrode, an orthogonal projection of the gate electrode on the base substrate in a second direction is located within an orthogonal projection of the first electrode on the base substrate in the second direction, and the second direction intersects with the first direction; and
wherein the display substrate or the opposite substrate comprises a black matrix, the black matrix comprises a first section extending in the first direction, and the orthogonal projection of the gate electrode on a base substrate and the orthogonal projection of the first electrode on the base substrate are both located within an orthogonal projection of the first section on the base substrate.

42. The display panel according to claim 41, wherein a ratio of a width of the first section in a second direction to a width of a gate line in the second direction is greater than or equal to 2.6 and smaller than 3.5.

43. The display panel according to claim 41, wherein an orthogonal projection of a symmetry axis of the first section extending in the first direction on the base substrate approximately coincides with an orthogonal projection of a symmetry axis of the first electrode extending in the first direction on the base substrate.

44. The display panel according to claim 43, wherein on two sides of the symmetry axis of the first section extending in the first direction, the orthogonal projection of the first section on the base substrate extends by a same distance relative to an orthogonal projection of the first electrode on the base substrate;
wherein on a same side of the symmetry axis of the first section extending in the first direction, a distance between the orthogonal projection of the first section on the base substrate and the orthogonal projection of the first electrode on the base substrate in the second direction is 1.15 μm-1.5 μm.

45. The display panel according to claim 41, wherein the opposite substrate further comprises a spacer;
the black matrix further comprises a second section and a third section provided on two sides of the first section respectively, the first section comprises a sub-section located between the second section and the third section, and a shape of a spliced pattern of the second section, the sub-section and the third section is the same as a shape of an orthogonal projection of the spacer on the base substrate; and
the orthogonal projection of the spacer on the base substrate is located within an orthogonal projection of the spliced pattern on the base substrate, and the orthogonal projection of the second electrode on the base substrate is located within the orthogonal projection of the spliced pattern on the base substrate.

46. A display apparatus, comprising the display panel according to claim 41.
